(19) United States
(12) Patent Application Publication
(10) Pub. No.: US 2009/0181506 A1
(43) Pub. Date: Jul. 16, 2009

(54) Novel Method to Form Memory Cells to Improve Programming Performance of Embedded Memory Technology

(75) Inventors: Jihong Chen, Plano, TX (US); Eddie Hearl Breashears, Allen, TX (US); Xin Wang, Plano, TX (US); John Howard Macpeak, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/407,624

(22) Filed: Mar. 19, 2009

Related U.S. Application Data
(62) Division of application No. 11/443,779, filed on May 31, 2006.

(51) Int. Cl. H01L 21/8239; H01L 21/426

(52) U.S. Cl. 438/232; 438/527; 257/E21.474; 257/E21.645

(57) ABSTRACT

An embedded memory device and method of forming MOS transistors having reduced masking requirements and defects using a single drain sided halo implant in the NMOS FLASH or EEPROM memory regions is discussed. The memory device comprises a memory region and a logic region. Logic transistors within the logic region have halos implanted at an angle underlying the channel from both drain and source region sides. Asymmetric memory cell transistors within the memory region receive a selective halo implant only from the drain side of the channel and not from the source side to form a larger halo on the drain side and leave a higher dopant concentration more deeply into the source side. One method of asymmetrically forming memory cell transistors comprises masking over the memory region; halo implanting a first conductivity dopant in NMOS regions of the logic region in first and second implant directions; masking over the logic region; halo implanting the first conductivity dopant in NMOS regions of the memory region in the second implant direction only, thereby reducing the number of masks required; masking over the memory region; halo implanting a second conductivity dopant in PMOS regions of the logic region in the first and second implant directions.

### CROSS-REFERENCE TO RELATED APPLICATIONS

This is a division of application Ser. No. 11/443,779, filed May 31, 2006, the entire disclosure of which is hereby incorporated by reference.

### FIELD OF THE INVENTION

The present invention relates generally to semiconductor devices and more particularly to memory devices and methods of manufacturing asymmetric memory cells using a single halo implant selective to the drain side to reduce the number of masks required and to improve programming performance in embedded memory technologies.

### BACKGROUND OF THE INVENTION

A conventional MOS transistor generally includes a semiconductor substrate, such as silicon, having a source, a drain, and a channel positioned between the source and drain. A gate stack composed of a conductive material (a gate conductor), an oxide layer (a gate oxide), and sidewall spacers, is typically located above the channel. The gate oxide is typically located directly above the channel, while the gate conductor, generally comprised of polycrystalline silicon (poly or polysilicon) material, is located above the gate oxide. The offset and sidewall spacers protect the sidewalls of the gate conductor.

Memory devices, for example, electrically erasable, programmable read only memory (EEPROM), and FLASH or EEPROM memory use a mixture of such MOS transistors on an integrated circuit chip which may include low voltage CMOS (LVCMOS), high voltage CMOS (HVCMOS), and the memory array or FLASH/EEPROM memory array areas. Such MOS transistor areas are commonly embedded together utilizing embedded memory technologies to integrate these LVCMOS, HVCMOS, and FLASH/EEPROM memory cell arrays together. For example, an embedded memory device may include carefully tailored memory cell transistors utilized in the memory array (FLASH/EEPROM region) as well as general purpose CMOS logic transistors used in various peripheral control circuits (peripheral or logic region) which control access to the array and perform various other control or CPU functions.

Embedded FLASH/EEPROM arrays range from very large arrays, (e.g., utilizing kbits, Mbits), where the need for a smaller area may justify considerably greater process complexity, through the very small examples (e.g., several dozens of bits) where keeping the added process complexity to a minimum justifies a larger area for each bit. Thus, the very large memory arrays generally utilize greater process complexity such as more masking steps and layers to obtain smaller cells, while smaller array application may utilize less process complexity such as single level poly (SLP) to save process costs utilizing larger area cells.

For example, It is common to add as many a six photo mask operations and associated processing steps in an effort to achieve a high density of memory bits when embedding FLASH memory to digital CMOS. Some of these process operations that are used to fabricate higher density FLASH/EEPROM (e.g., stack etch, where multiple layers are etched or patterned using a single masking layer, or additional layers of poly-crystalline silicon and multiple thicknesses of gate or tunnel oxide) are operations that are not normally required to build designs without FLASH/EEPROM. These process operations add cost and may require specialized equipment and skills.

Thus, there is significant motivation to minimize the number of masks required to accomplish the high levels of integration utilized in embedded FLASH memory devices, particularly at the higher end of the spectrum of process costs in higher density embedded FLASH.

The basic FLASH/EEPROM storage element is called a floating gate transistor. One prior-art floating-gate transistor has a source S, a polysilicon floating gate (FG) storage node with no connection permitted, and a drain (D). The gate is said to float without any direct electrical contact, embedded within a high-quality insulator, with the floating gate capacitively charge coupled through an electrically isolated control gate (CG). A charge placed on such a floating gate typically represents a data state or bit of data, and may be retained for about a decade or more.

FLASH/EEPROM memories using Fowler-Nordheim (F-N) tunneling are often programmed by applying a relatively high voltage level of from about 5 volts to about 30 volts across a tunneling region (e.g., a tunnel oxide or gate oxide) for a controlled period of time. Typical tunnel oxide thicknesses range from about 50 Angstroms to about 200 Angstroms. The silicon under at least part of the tunnel oxide area is doped sufficiently to avoid excessive depletion when programming voltages are applied. Electrons are placed on the floating gate storage node as charge flows through the gate oxide or tunnel oxide, reducing the electric field as the current falls towards zero. A reversed polarity results in reverse charge flow, providing the ability for a large but finite number of write/erase cycles.

FLASH/EEPROM memory is typically arranged as a matrix of memory cells fabricated in an integrated circuit chip, and address decoding in the chip allows access to each cell for read/write functions. These FLASH memory cells are often arranged in rows so that blocks of data such as words or bytes can be written or read simultaneously. FLASH EPROM and EEPROM memory cells have many variations.

FLASH memory cells of arrays may also be formed as MOS transistors having asymmetric source and drain regions to provide better programming performance than symmetrically formed structures. One prior art provides an asymmetric structure using birds beak like structures underlying the edge of the gate in the channel region. Another prior art forms an asymmetric structure using offset and varied thickness gate oxides. However, such asymmetric flash cell structures having asymmetric physical geometries may require careful alignment tolerances and/or one or more associated masks which may result in higher manufacturing costs.

Accordingly, there is a need for an improved memory cell of an embedded memory device and method that effectively provides asymmetric source and drain formation while reducing the number of masks required and the probability of damage defects during implantation in order to improve programming performance in embedded memory technologies.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention relates to a device and method of fabrication, wherein the MOS transistors, for example, generally NMOS transistors of an FLASH memory device having FLASH array, low voltage CMOS (LVCMOS) regions, and/or high voltage CMOS (HVCMOS) (e.g., logic control, peripheral, or processing portions) exhibit improved programming performance (e.g., shorter programming time) due to the asymmetric formation of source and drain regions in the (e.g., NMOS) FLASH region. Conventionally, this asymmetry may be accomplished with an additional mask and implants.

The present invention, however, beneficially accomplishes this goal by utilizing a single halo implant selectively implanted from the drain side of the MOS transistors without any EE mask other than the gate stack. Consequently, less dopant is implanted on the source side, thereby allowing a greater dopant concentration to remain on the source side of the gate and to a greater depth. Therefore, one masking process is avoided, one halo implant is eliminated (along with the two 90° wafer rotations), and the additional damage defects introduced by implanting the source are also avoided. The asymmetric FLASH structure has been shown to provide a higher electrical field near the drain side for the same bias levels, which produces a higher hot electron injection current to the gate and a shorter programming time than symmetric structures.

In accordance with one aspect of the present invention, an embedded memory device having a LVCMOS or logic region and a FLASH or EEPROM region comprises one or more CMOS logic transistors within the LVCMOS region of the memory device, the logic transistors having a semiconductor body of a first conductivity type, source and drain regions of a second conductivity type formed in the semiconductor body on opposing sides of a channel. The device also has substantially symmetric halo regions implanted using the first conductivity type at an angle underlying a channel into both of the source and drain regions, the halos implanted from both source and drain region sides of the channel.

The memory device further comprises one or more asymmetric FLASH/EEPROM memory cell transistors within the FLASH/EEPROM region of the device, the cell transistors having a semiconductor body of the first conductivity type and source and drain regions of the second conductivity type formed in the semiconductor body on opposing sides of a channel. The device also comprises asymmetric halo regions implanted using the first conductivity type at an angle underlying the channel of the memory cell transistors, selectively implanted only from the drain side of the channel and not from the source side of the channel, wherein the halo formed on the drain side is substantially larger than the halo formed on the source side, and wherein a greater dopant concentration is provided on the source side than on the drain side.

In one aspect of the invention, the FLASH memory cell transistors of the embedded memory device have a semiconductor body of the first conductivity type comprising NMOS transistors of a 1T FLASH/EEPROM cell.

In accordance with a method of the present invention, asymmetric FLASH memory cell transistors are formed in an embedded FLASH memory device. The method comprises masking over the FLASH/EEPROM array region; halo implanting a first conductivity (e.g., p-type) dopant in NMOS regions of the LVCMOS or logic region in first and second implant directions; masking over the logic region; halo implanting the first conductivity dopant in NMOS regions of the FLASH/EEPROM region in the second implant direction only, thereby reducing the number of masks required; masking over the FLASH/EEPROM region; halo implanting a second conductivity dopant (e.g., n-type) in PMOS regions of the logic region in the first and second implant directions. Thereafter, conventional back-end processes may be utilized.

In accordance with another aspect of the present invention, a method of asymmetrically forming FLASH memory cell transistors is provided, wherein a gate structure is formed over a semiconductor body, thereby defining a channel region therebelow in the semiconductor body. The method further comprises masking over the FLASH/EEPROM array region; halo implanting a first conductivity (e.g., p-type) dopant in NMOS regions of the logic region in first and second implant directions; masking over the logic region; halo implanting the first conductivity dopant in NMOS regions of the FLASH/EEPROM region in the second implant direction only, thereby reducing the number of masks required; masking over the FLASH/EEPROM region; halo implanting a second conductivity dopant (e.g., n-type) in PMOS regions of the logic region in the first and second implant directions. Thereafter, conventional back-end processes may be utilized.

In another aspect, the first conductivity type is p-type and the second conductivity type is n-type, and wherein the halo formed asymmetrically on the source side of the memory cell transistors is laterally displaced away from the channel further than the halo formed on the drain side as a result of the single drain side halo implant.

In yet another aspect, the halo implanting in the first implant direction comprises implanting at an angle underlying the channel from the source region side of the channel, and the halo implanting in the second implant direction comprises implanting at an angle underlying the channel from the drain region side of the channel.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIGS. 1A and 1B are top plan and side views illustrating four quadrants or “rotations” of angled, pocket, or halo implantations for implanting active regions in a substrate or semiconductor body of a wafer such as may be used in accordance with the present invention;

FIG. 2A is a block diagram of an exemplary embedded FLASH/EEPROM memory device such as may be used in accordance with one or more aspects of the present invention, the device having FLASH/EEPROM, logic regions comprising LVCMOS and/or HVCMOS regions;

FIG. 2B is a schematic diagram of an array of conventional 1T FLASH EEPROM memory cells such as may be used in the FLASH/EEPROM region of the embedded FLASH/EEPROM memory device of FIG. 2A;

FIGS. 3A and 3B are a cross-sectional side view and a corresponding doping concentration view, respectively, illustrating a conventional symmetrically formed floating gate transistor used as a memory cell of a FLASH or EEPROM array of FIGS. 2A and 2B, formed using a FLASH or EE mask pattern that determines FLASH/EEPROM regions to be implanted by two symmetric halo implants from opposing directions corresponding to both source and drain region sides of the cell, further illustrating the symmetric pattern of doping that results within the semiconductor body during the two symmetric halo implants;

FIGS. 4A and 4B are a cross-sectional side view and a corresponding doping concentration view, respectively, illustrating an exemplary asymmetrically formed floating gate transistor used as a memory cell of a FLASH/EEPROM array, formed in accordance with the present invention without using an extra FLASH/EE mask pattern, and implanted by a single asymmetric halo implant from only one select direction corresponding to a drain region side of the cell, further illustrating the asymmetric pattern of doping that results within the semiconductor body during the single asymmetric halo implant that is shadowed by a gate stack;

FIG. 5A-5E are exemplary plots of doping, potential, Ex, Ey, and Em all plotted vs the X position on the asymmetric FLASH/EEPROM cell of FIG. 4A such as may be used in accordance with the present invention, and contrasting the results to those obtained from the conventional symmetric cell of FIG. 3A;

FIG. 6 is a flow diagram illustrating an exemplary method of forming an asymmetric FLASH/EEPROM cell of an embedded FLASH/EEPROM memory device in accordance with an aspect of the present invention, the device having FLASH/EEPROM, logic regions;

FIG. 7 is a top plan view of an exemplary array of asymmetric FLASH/EEPROM cells, similar to the asymmetric cell of FIG. 4A formed in accordance with the method of FIG. 6, and further illustrating an isolation region provided between the asymmetrically formed source and drain regions of neighboring cells to accommodate the doping differences produced between the source and drain regions and metal contacts subsequently formed thereon;

FIG. 8 is a cross-sectional side view of a conventional array of symmetrically formed floating gate transistors used as memory cells of a FLASH or EEPROM array similar to that of FIGS. 2A and 2B, formed using a FLASH/EE mask pattern that determines FLASH/EEPROM regions to be implanted by two symmetric halo implants from opposing directions corresponding to both source and drain region sides of the cell, further illustrating a bitline contact that connects the combined source and drain regions to a common first metal level; and

FIG. 9 is a cross-sectional side view of an exemplary array of asymmetrically formed floating gate transistors used as memory cells of a FLASH or EEPROM array similar to that of FIGS. 2A and 7, formed in accordance with the present invention without using an extra EE mask pattern, and implanted by a single asymmetric halo implant from only one select direction corresponding to a drain region side of the cell, further illustrating the isolation region between the source and drain regions and separate bitline contacts that individually connect the source and drain regions to the first and a second metal level, respectively.

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale. The invention provides an asymmetric MOS transistor structure for FLASH/EEPROM memory devices and methods in which cell programming times are improved while minimizing defects and eliminating a masking operation, by using a single halo implant selective to the drain region of the cell transistors in the FLASH/EEPROM region of embedded memory devices. These concepts and benefits are further revealed in association with the following exemplary figures and discussions.

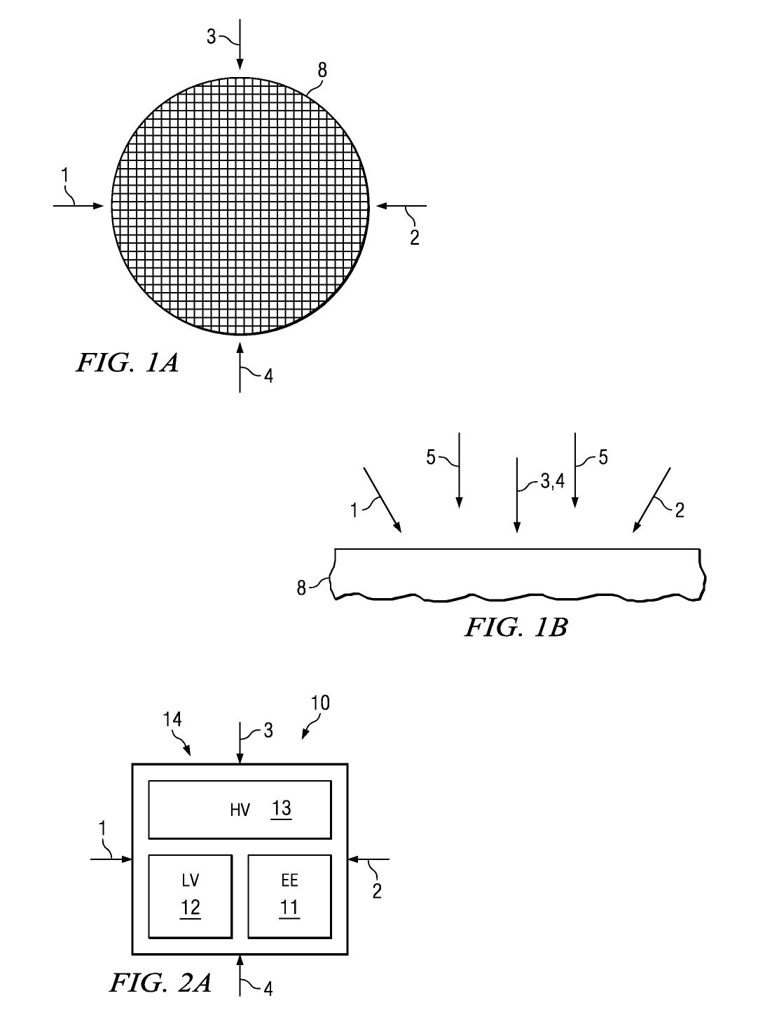

FIGS. 1A and 1B, for example, illustrate four quadrants or “rotations” of an angled or pocket implantation for implanting dopants into active regions (e.g., source and drain regions) of a substrate of a wafer 8 (e.g., semiconductor wafer) in accordance with the present invention utilizing a resist mask pattern in the fabrication of embedded memory devices. Angled, pocket, or halo implants 1 and 2, for example, are rotated about 180° from each other (laterally opposed), and are also tilted at an angle relative to the surface of the wafer 8. Similarly, implant rotations 3 and 4 are rotated about 180° from each other, and are also tilted at an angle relative to the surface of the wafer 8. In this way, four angled implants (e.g., at 0°, 90°, 180 °, 270°, or 45°, 135°, 225°, 315°) are conventionally utilized at one of each of the four quadrants or “quads” of the available 360° around a wafer to insure adequate dose exposure of all the transistor active regions of a semiconductor device and as masked by the resist pattern. Although the wafer or a platter containing multiple wafers is typically rotated while the implanter beam is held fixed, the implanter could potentially be rotated about the wafer if desired.

In addition, a regular or “normal implant” 5 may also be utilized to implant dopants, wherein the beam impacts the wafer at an angle normal or perpendicular to the surface of the wafer 8. For example, normal implants 5 as well as angled implants 1, 2, 3, 4 to the semiconductor substrate of wafer 8 may be utilized to form low density drain LDD regions therein alongside gate structures for example. The LDD regions are formed by normal 5 or angled implantations 1, 2, 3, 4 using appropriate dopant species atoms through openings in the mask or resist layer. The LDD implant is typically implanted substantially perpendicular to the surface of the substrate or wafer 8 (at a 0° angle), so an unrestricted LDD region width is available as an opening for the LDD implantation.

In some semiconductor cells, all features (e.g., active regions or gates) are oriented in one direction. In such cases, a pair of pocket or halo implants may be used to introduce dopants into both sides of these active regions or under both sides of the gate in the channel region. These implants may be referred to as “two rotations”, from the use of two 90° rotations of the wafer mounting disc in an ion implanter. The features of other semiconductor cells may have multiple orientations, wherein four pocket rotations are typically used to implant both sides of all features substantially equally. Pocket shadowing from the edge of the mask or the gate structure of a cell may occur from any direction, including the directions parallel to, or perpendicular to these features. Generally speaking, such pocket shadowing has produced detrimental results in MOS transistors, however, the shadowing from the gate structure is advantageously used in association with the asymmetrically formed cell transistors of the present invention.

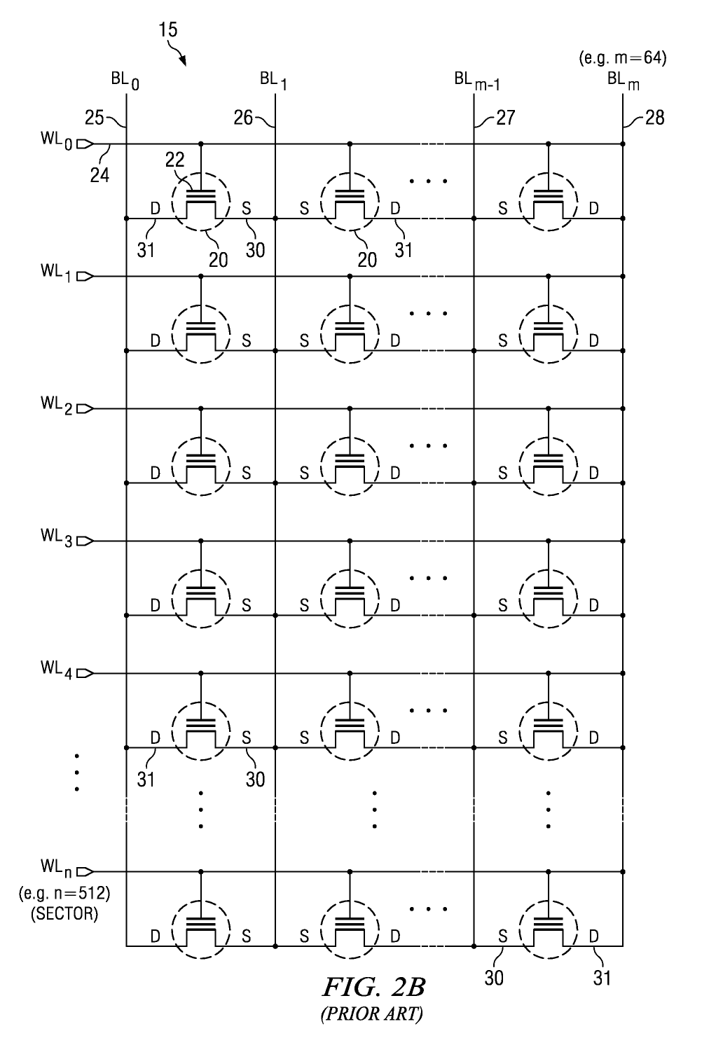

Referring now to FIG. 2A, an embedded memory device 10 is illustrated such as may be used in accordance with one or more aspects of the present invention. The memory device 10 comprises, for example, a semiconductor integrated circuit chip having a memory array or FLASH/EEPROM region 11 comprising an array of FLASH/EEPROM memory cells, a low voltage CMOS or LVCMOS region 12 for logic, memory control, or processing functions, and/or a high voltage CMOS or HVCMOS region 13 for voltage level shifting, or other higher voltage control functions. Collectively, the LVCMOS region 12 and/or the HVCMOS region 13 may comprise a peripheral or logic region 14 of the memory device 10. The LVCMOS region 12, for example, may accomplish various memory control and logic functions associated with accessing, reading, and writing operations on the FLASH/EEPROM region 11, and other non-memory related functions of the embedded memory device 10. The FLASH/EEPROM region 11 comprises an array of FLASH memory cells, for example, an array of 1T FLASH/EEPROM memory cells 20 of FLASH/EEPROM memory array 15 of FIGS. 2A and 2B. FIG. 2A further illustrates four exemplary pocket or halo implantation directions 1, 2, 3, and 4 for implanting various dopant species and as will be discussed further infra.

FIG. 2B illustrates an array 15 of conventional 1T FLASH or EEPROM memory cells 20 such as may be used in the FLASH or EEPROM region 11 of the embedded FLASH/EEPROM memory device 10 of FIG. 2A.

FIG. 2B illustrates a prior art flash memory array 15 utilizing a “virtual ground” architecture. The typical virtual ground architecture of flash memory array 15, for example, comprises 512 rows 24 of flash cells 20 with its stacked gate terminal 22 coupled to an associated word line (e.g., WL0 thru WLn) 24, and 64 columns (25, 26, 27, 28) of neighboring flash cell pairs (20a & 20b) with a drain 31 of one transistor 20b coupled to an associated bit line (e.g., BL0 thru BLm) and the drain 31 of the adjacent transistor 20a coupled to the same bit line 26. In addition, each single row of flash cells (e.g., 20a & 20b) associated with a word line 24 is connected in series, with the source 30 of one cell 20a coupled to the source 30 of an adjacent cell 20b, wherein each drain terminal of the transistors within a single column is connected to the same bit line. (Note: usually in the prior art, source connects to source, and drain connects to drain of adjacent memory cells. In addition, the contacts to source and drain are usually separated, and the voltages which are applied to source and drain are usually different)

An individual FLASH cell is selected via the word line and a pair of bit lines bounding the associated cell. For example, in reading the FLASH cell 20a, a conduction path would be established when a positive voltage is applied to the bit line (BL0) 25 coupled to the drain of FLASH cell 20a, and the source 30 which is coupled to the bit line (BL1) 26, is selectively coupled to ground (VSS). Thus, a virtual ground is formed by selectively switching to ground the bit line associated with the source terminal of only those selected FLASH cells which are to be programmed or read.

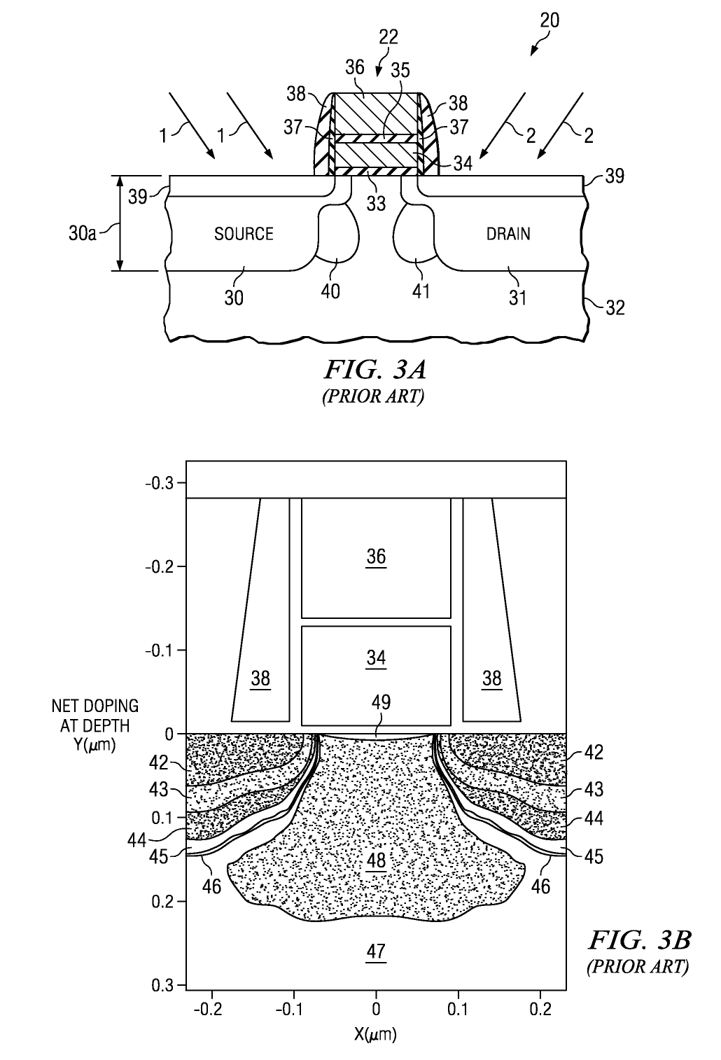

FIGS. 3A and 3B illustrate a cross-sectional side view and a corresponding doping concentration view, respectively, of a conventional symmetrically formed floating gate transistor 20 that may be used as a FLASH memory cell 20 of a FLASH EEPROM array 15 of FIGS. 2A and 2B. FLASH cell 20 comprises a semiconductor body 32 (e.g., a p-type substrate material) having source 30 and drain 31 regions formed symmetrically within the substrate 32 on opposing sides of the gate stack 22. The gate stack 22 comprises a gate oxide dielectric 33 formed overlying the substrate 32 in a channel region. The gate stack 22 further comprises a first polysilicon floating gate 34 formed over the gate oxide 33, an insulating material 35 formed over the floating gate 34, and a second polysilicon material 36 formed over the insulating material 35.

Offset spacers 37 may then be formed over the lateral sidewalls of the gate stack 22 to help direct or align an LDD implant region 39 to the lateral edges of the offset spacers 37. Halo implants 1 and 2 from and corresponding with both the source 30 and drain 31 sides, respectively, of the cell 20 are implanted at an angle under the channel region to form symmetric source and drain halos 40 and 41, respectively. Thereafter, sidewall spacers 38 may then be formed over the lateral sidewalls of the offset spacers 37 to direct the deep source/drain implant.

Conventional FLASH cell 20 is formed symmetrically, for example, in one or more FLASH/EEPROM regions 11, which are implanted by the two halo implants (e.g., 1 and 2), symmetrically from opposing directions (e.g., implant rotations 1 and 2, or 3 and 4), corresponding with both source and drain region sides of the cell 20. The symmetrical cell structure requires an EE mask pattern that provides an opening in the one or more FLASH/EEPROM regions 11, while covering the LVCMOS 12 and HVCMOS regions 13, for example.

To make the symmetric structure into the more advantageous asymmetric structure, however, an additional (second) EE mask would be needed to cover the source region 30 during halo implantations (e.g., rotations 1 and 2) in order to implant more dopant at the drain region 31. In particular, the FLASH/EE mask pattern provides an opening in the one or more FLASH/EEPROM regions 11, while covering the LVCMOS 12 and HVCMOS regions 13. This extra EE mask is not required, however, in the method of the present invention, which instead uses a single sided halo implant selective to the drain region.

FIG. 3B further illustrates the symmetric pattern of doping that is produced within the semiconductor body 32 as a result of the two symmetric halo implants (e.g., 1 and 2). Also note from FIG. 3B, that the shape and depth of the dopant concentration is substantially symmetrical on either side of X=0 (the center of the gate 22 or channel).

The net dopant concentrations of FIG. 3B are illustrated in several crosshatch regions ranging from a higher positive signed log dopant level 42, down to successively lower levels 43, 44, and 45 to a zero net doping level 46, where n-type and p-type levels are at about the same net levels. (Assuming an n-type dopant is positive and a p-type dopant is negative, a more positive dopant concentration generally means a higher n-type dopant concentration, and a more negative dopant concentration generally means a higher p-type dopant concentration) Increasingly more negative dopant concentrations are illustrated at dopant levels 47, 48, and finally to the most negative signed log dopant level 49. In one implementation, for example, these dopant levels may range from over 1E21 ions/cm³ down to about −2E18 ions/cm³.

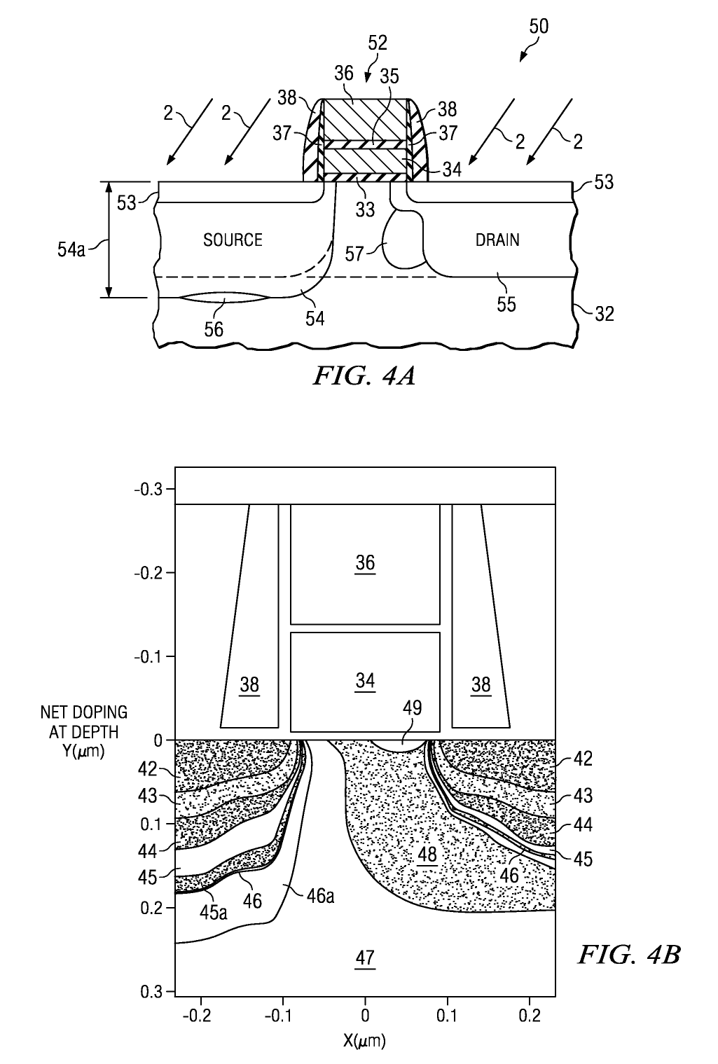

FIGS. 4A and 4B illustrate a cross-sectional side view and a corresponding doping concentration view, respectively, of an exemplary asymmetrically formed floating gate transistor 50 such as may be used as a FLASH memory cell 50 of a FLASH EEPROM array, formed in accordance with the method of the present invention.

FLASH cell 50 similarly comprises a semiconductor body 32 (e.g., a p-type substrate material) having source 54 and drain 55 regions formed asymmetrically within the substrate 32 on opposing sides of the gate stack 52. The gate stack 52 comprises a gate oxide dielectric 33 formed overlying the substrate 32 in a channel region. The gate stack 52 further comprises a first polysilicon floating gate 34 formed over the gate oxide 33, an insulating material 35 formed over the floating gate 34, and a second polysilicon material 36 formed over the insulating material 35.

An offset spacer 37 and a sidewall spacer 38 may then be formed over the lateral sidewalls of the gate stack 52 to help direct or align an LDD implant region 53 to the lateral edges of the sidewall spacer 38. The halo implant (e.g., implant rotation 2), selectively implanted from only the drain 55 side of the cell 50, is implanted at an angle under the channel region to form asymmetric source halos 56 and drain halos 57, respectively.

FLASH cell 50 is asymmetrically formed in accordance with the method of the present invention, without using an extra (second) EE mask pattern, such as would be required to convert the symmetric cell 20 of FIG. 3A into the improved asymmetric cell 50. In accordance with the present invention, one or more FLASH/EEPROM regions 11 may be implanted by a single halo implant (e.g., implant rotation 2) from only one direction (e.g., implant rotation or direction 1, 2, 3, or 4), the implant direction corresponding with the drain region 55 side of the cell 50. The asymmetrical cell structure, however, does requires one EE mask pattern that provides an opening in the one or more FLASH/EEPROM regions 11, while covering the LVCMOS 12 and HVCMOS regions 13, for example. In addition to the single sided halo implant, the gate stack 52 also significantly contributes to block dopant implantation, thereby keeping the source side n+ dopants from being neutralized by the p− dopants of the halo implant.

FIG. 4B further illustrates the asymmetric pattern of doping that is produced within the semiconductor body 32 as a result of the single asymmetric halo implant (e.g., implant rotation 2). FIG. 4B also demonstrates that the source depth 54a of the dopant concentration is substantially deeper and more concentrated on the source region 54 side of the transistor 50 and is therefore asymmetric about X=0 (the center of the gate 52 or channel).

Similar to the net dopant concentrations of FIG. 3B, FIG. 4B illustrates several crosshatch regions that range from a higher positive signed log dopant level 42, down to successively lower levels 43, 44, 45 and 45a to a zero net doping level 46. Increasingly more negative dopant concentrations are illustrated at dopant levels 46a, 47, 48, and finally to the most negative signed log dopant level 49. (Assuming an n-type dopant is positive and a p-type dopant is negative, a more positive dopant concentration generally means a higher n-type dopant concentration, and a more negative dopant concentration generally means a higher p-type dopant concentration)

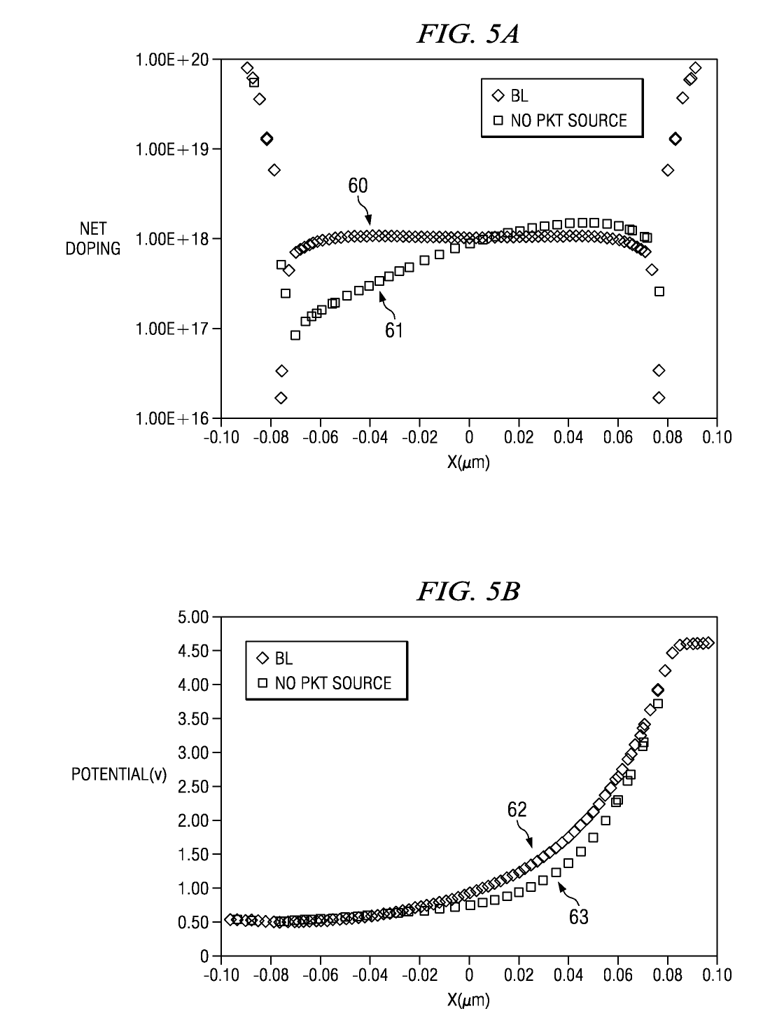

FIG. 5A-5D illustrate plots of net doping, potential, Ex, Ey, and Em all plotted vs the X position for an exemplary asymmetric cell, such as FLASH EEPROM cell 50 of FIG. 4A, used in accordance with the present invention, and contrasted with results obtained from a conventional symmetric cell similar to that of cell 20 of FIG. 3A. In particular, the data represented in even numbered plot (e.g., plot 60) for the symmetric cell 20 represents base line data (BL), while the data for the odd numbered plot (e.g., plot 61) for the asymmetric cell 50 is produced as a result of no halo implant from the source region side of the cell. In each of the plot figures, the left side (−X quantities) represents the source side of the corresponding cell, while the right side (+X quantities) represent the drain side of the corresponding cell.

FIG. 5A, for example, illustrates plots 60 and 61 of the net doping vs the X position (along the channel length) of symmetric cell 20 and asymmetric cell 50, respectively. As would be expected, plot 60 for the symmetric cell 20 has a relatively flat net doping concentration across the channel length, while plot 61 for the asymmetric cell 50 shows a dramatic increase in the implanted net doping between the source and drain region sides of the channel. It should also be noted that the channel doping levels of the asymmetric cell 50 have been adjusted to bring the Vt level to about the same Vt level of the symmetric cell 20. Thus, when the Vt levels are about the same, the drive current of the asymmetric cell 50 is higher than the drive current of the symmetric cell 20.

FIG. 5B illustrates plots 62 and 63 of the potential voltage vs the X position of symmetric cell 20 and asymmetric cell 50, respectively. Plots 62 and 63 have about the same voltages on the drain and source, but the potential of plot 63 of the asymmetric cell 50 increases more radically nearer the drain region side of the channel which results in a higher electrical field near the drain side. This is a further indication of the non-uniform dopant distribution generating higher electrical field near drain.

FIG. 5C illustrates plots 64 and 65 of the electric field component in the X direction (Ex, along or parallel to the channel length) in volts per centimeter vs the X position of symmetric cell 20 and asymmetric cell 50, respectively. Note that plot 65 of the asymmetric cell 50 increases to a higher level nearer the drain region side of the channel which is needed for hot electron generation, which demonstrates that an asymmetric cell 50 can result in a higher electrical field and generate more hot electrons.

FIG. 5D illustrates plots 66 and 67 of the electric field component in the Y direction (Ey, perpendicular to the channel length) in volts per centimeter vs the X position of symmetric cell 20 and asymmetric cell 50, respectively. Note that plot 67 of the asymmetric cell 50 demonstrates a more nonlinear relationship between the source and drain regions. Ey of asymmetric cell 50 is about the same as a symmetric cell 20 near the drain side which is needed for hot electron injection. This is a further indication of the non-uniform dopant distribution and the masking effect of the gate stack.

FIG. 5E illustrates plots 68 and 69 of the magnitude of the electric field (Em) in volts per centimeter vs the X position of symmetric cell 20 and asymmetric cell 50, respectively. Plots 68 and 69 are therefore the resultant product of the plots of Ex and Ey. Plot 69 of the asymmetric cell 50 demonstrates a more nonlinear relationship between the source and drain regions as well as the non-uniform dopant distribution which is achieved. The Em of asymmetric cell 50 is higher than symmetric cell 20 near the drain side, thus more hot electrons of the asymmetric cell 50 can be generated and injected to the floating gate, therefore provide better programming than the symmetric cell 20.

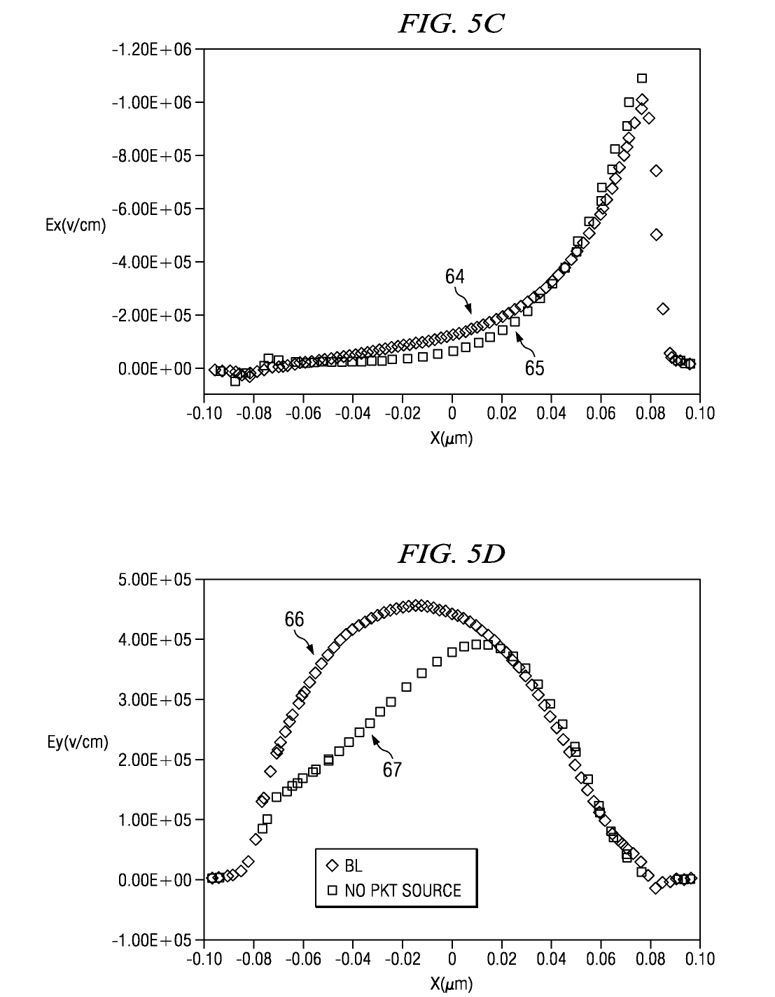

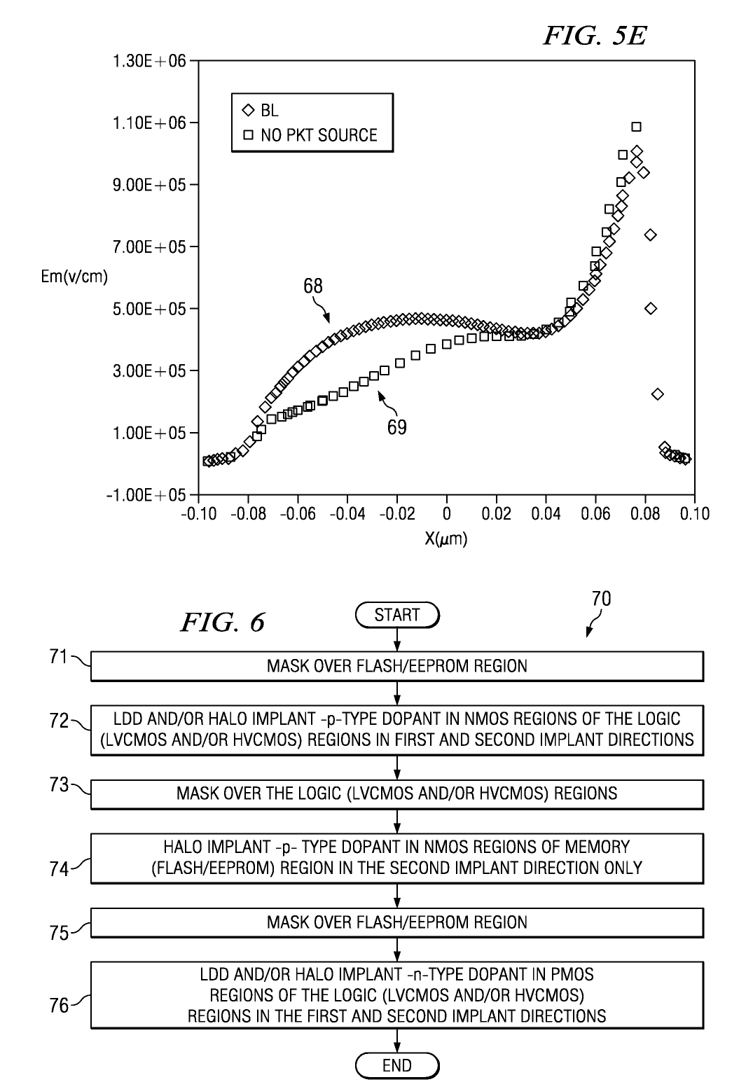

Referring now to FIG. 6, further aspects of the invention relate to exemplary methods of fabricating asymmetric FLASH EEPROM cells of an embedded FLASH/EEPROM memory device, wherein FIG. 6 illustrates an exemplary method 70 in accordance with the invention, and FIG. 4A illustrates the exemplary MOS transistor of a FLASH EEPROM memory cell 50, and FIG. 7 illustrates an array 100 of nine FLASH EEPROM memory cells 50 in accordance with the invention. For example, the embedded FLASH/EEPROM memory device may comprise FLASH EEPROM 11, LVCMOS 12, and HVCMOS regions 13 similar to that of memory device 10 of FIG. 2A, when formed in accordance with an aspect of the present invention. Again, the LVCMOS region 12, and/or the HVCMOS region 13 may comprise a peripheral or logic region 14 of the memory device 10 of FIG. 2A which may be formed symmetrically, and the FLASH EEPROM region 11 may be formed asymmetrically in accordance with the method 70 of FIG. 6.

While the exemplary method 70 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the fabrication of MOS transistors, FLASH EEPROM cells, ICs and composite transistors illustrated and described herein, as well as in association with other cells, transistors, and structures not illustrated, including but not limited to NMOS and/or PMOS composite transistors formed in the memory region and the logic region of an embedded FLASH memory device.

Initially, before the method 70 begins transistor fabrication may be initiated by the formation of gate structures in peripheral or logic regions (e.g., logic region 14 comprising LVCMOS 12 and/or HVCMOS 13 regions of FIG. 2A) and memory array (FLASH/EEPROM) region 11 of the embedded memory device 10, wherein transistor well formation and isolation processing may be initially performed. Thus, NMOS and PMOS regions may be initially defined, wherein NMOS regions comprise a P-well in which n-type source/drain regions will later be formed, and PMOS regions comprise an N-well in which p-type source/drain regions will later be formed, respectively. In addition, isolation regions may comprise shallow trench isolation (STI) or field oxide regions (FOX) that serve to define various active areas and electrically isolate various active areas laterally from one another.

Method 70 then begins at 71, wherein a mask is formed over the structures in memory array (FLASH/EEPROM) regions (e.g., 11 of FIG. 2A) of an embedded memory device (e.g., 10 of FIG. 2A), wherein openings are formed in the mask in the logic regions 14 (e.g., LVCMOS region 12 and/or HVCMOS region 13 of FIG. 2A). At 72, LDD, and/or halo implanting is initiated to implant a first conductivity dopant (e.g., −p-type) in NMOS regions of the logic regions 14 (e.g., LVCMOS region 12 and/or HVCMOS region 13 of FIG. 2A) of the device in both first and second implant directions (e.g., implant rotations 1 and 2). Note: for NMOS, LDD may be a second conductivity dopant (e.g., −n-type), and halo implanting may use a first conductivity dopant (e.g., −p-type)

At 73 a mask is formed over the logic regions 14 (e.g., LVCMOS region 12 and/or HVCMOS region 13 of FIG. 2A) of the embedded memory device (e.g., 10 of FIG. 2A), wherein openings are formed in the mask in the FLASH/EEPROM region (e.g., 11 of FIG. 2A). At 74, halo implanting, and optionally LDD implanting, where LDD is the second conductivity dopant (e.g., −n-type), is initiated to implant the first conductivity dopant (e.g., −p-type) in NMOS regions of the memory array (FLASH/EEPROM) region of the device in only the second implant direction (e.g., implant rotation 2).

At 75 a mask is formed over the memory array (FLASH/EEPROM) region (e.g., 11 of FIG. 2A) of the embedded memory device (e.g., 10 of FIG. 2A), wherein openings are formed in the mask in the LVCMOS regions (e.g., 12 of FIG. 2A). At 76, LDD and/or halo implanting is initiated to implant a second conductivity dopant (e.g., −n-type) in PMOS regions of the logic region 14 (e.g., LVCMOS region 12 and/or HVCMOS region 13 of FIG. 2A) of the device in both first and second implant directions (e.g., implant rotations 1 and 2). Note: for PMOS, LDD is first conductivity dopant (e.g., −p-type), halo implanting is second conductivity dopant (e.g., −n-type). Thereafter, the process ends, and other subsequent backend processes may be utilized.

For example, extension regions and source/drain regions may be subsequently formed in the active region of the silicon body. For example, lightly doped, medium doped or heavily doped extension region implants are performed in the NMOS and PMOS regions, or alternatively, the NMOS regions and PMOS regions may be implanted separately with differing dopants by mask off each region, respectively. Since the extension region implants are formed after the offset spacer, it is self-aligned with respect to the offset spacer, thereby placing both regions extremely close to the lateral edge of the gate structure within the semiconductor body. A thermal process such as a rapid thermal anneal may then be employed to activate the extension region dopants, which causes the extension regions to diffuse laterally underneath the offset spacer and slightly overlap the gate stack toward the channels.

Source/drain sidewall spacers may then also be formed on the gate structures. The sidewall spacers comprise an insulating material such as an oxide, a nitride or a combination of such layers. The spacers are formed by depositing a layer of such spacer material(s) over the device in a generally conformal manner, followed by an anisotropic etch thereof, thereby removing such spacer material from the top of the gate structure and from the moat or active area and leaving a region on the lateral edges of the gate structure, overlying the offset spacers. The sidewall spacers are substantially thicker than the offset spacers, thereby resulting in the subsequently formed source/drain regions to be offset from lateral edges of the gate structure. The source/drain regions are then formed by implantation, wherein a source/drain dopant is introduced into the exposed areas (top of gate electrode and active areas not covered by sidewall spacers). The source/drain regions are then completed with a thermal process to activate the dopant.

Other processing may then include silicide processing, wherein a metal layer is formed over the device, followed by a thermal process, wherein the metal and silicon interfaces react to form a silicide (on top of the gate and in the source/drain regions). Unreacted metal is then stripped away, and other back end processing such as interlayer dielectric and metallization layers are formed to conclude the device formation.

FIG. 7 illustrates an exemplary 3×3 array 100 of nine asymmetric FLASH EEPROM cells 50, similar to the asymmetric cell 50 of FIGS. 4A and 4B, formed in accordance with the method 70 of FIG. 6 in one aspect of the present invention. Similar to cell 50 of FIG. 4A, array 100 comprises a substrate or semiconductor body 32 having source (S) 54 and drain (D) 55 regions formed within active regions or moats 140 (e.g., NMOS or PMOS active regions). Array 100 further comprises the gate stack 52 comprising, for example, a polysilicon gate material 130 overlying the source/drain regions 54/55 and isolation regions (e.g., shallow trench isolation regions) STI 150 provided between the asymmetrically formed memory cell transistors 50. In particular, the isolation regions STI 150 are provided between the asymmetrically formed source S 54 and drain D 55 regions of neighboring cells 50 to accommodate the doping differences produced therein.

Metal contacts Met1 110 and Met2 120 are subsequently formed overlying and contacting the source S 54 and drain D 55 regions to provide separate bitline (BL) connections thereto. The isolation regions STI 150 between the source S 54 and drain D55 regions of neighboring memory cells and the extra set of metal bitline connections thereto, are only needed because the asymmetric doping differences between the source and drain regions require and produce different BL voltages on the respective source and drain terminals during memory operations.

Halo implant rotation 2 is shown on the right hand side of the array 100, illustrating the direction of the single halo implant selective to the drain side of the gate 130 or channel. Advantageously, this single-sided halo implant avoids the additional defects associated with implanting a second time on the source side of the gate/channel, avoids the second implant rotation and time required, and avoids the added mask and costs required of a mask produced asymmetry.

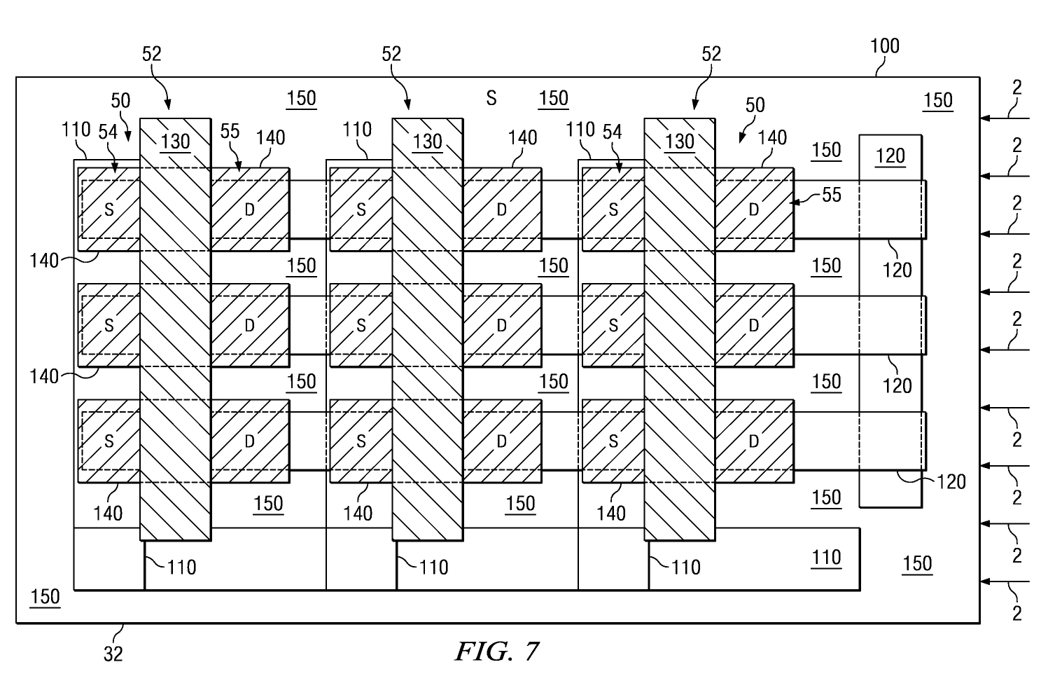

FIG. 8 illustrates a cross-sectional side view of a conventional array 15 of symmetrically formed FLASH memory cells 20 similar to those of FIG. 3A of a FLASH EEPROM array 15 similar to that of FIGS. 2A and 2B. As discussed previously in association with FIG. 3A, the cells 20 of array 15 are formed using a FLASH/EE mask pattern that determines FLASH/EEPROM regions (e.g., 11 of FIG. 2A) to be implanted by two symmetric halo implants from opposing directions (e.g., rotations 1 and 2) corresponding to both source 30 and drain 31 region sides of the cell 20.

The array 15 of FIG. 8 further illustrates a bitline contact 160 that connects the combined source and source regions 30 to a common first metal level (e.g., Metal level 1, Met1).

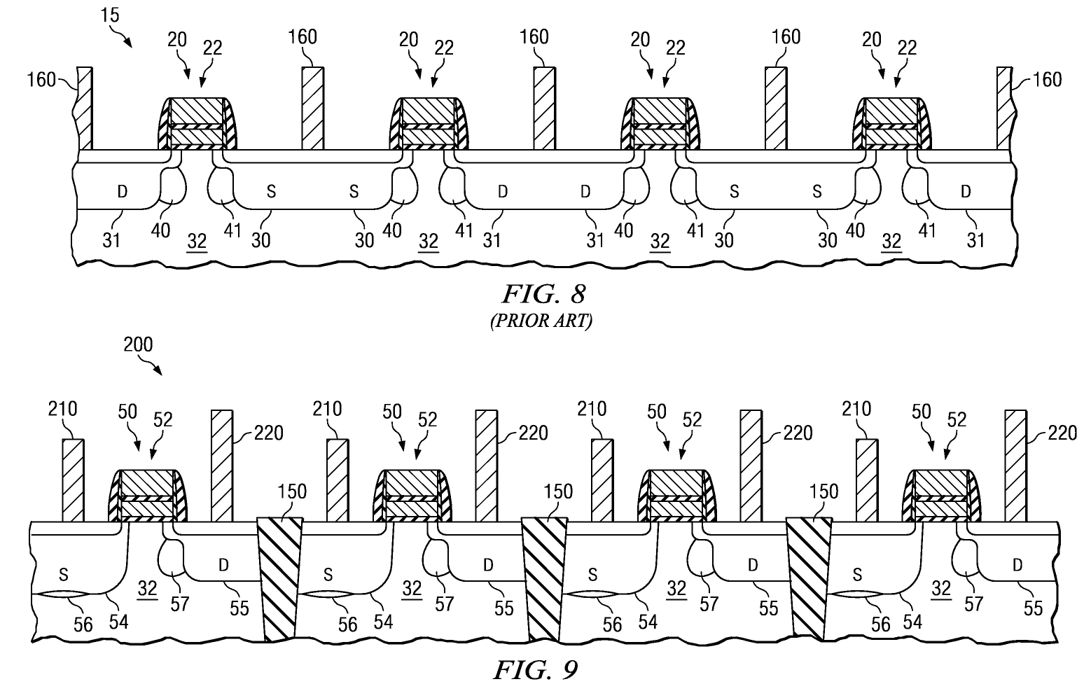

FIG. 9 illustrates a cross-sectional side view of an exemplary array 200 of asymmetrically formed FLASH memory cells 50 similar to those of FIG. 4A of a FLASH EEPROM array 200 similar to that of FIGS. 2A and 7, formed in accordance with the present invention. As discussed previously in association with FIG. 4A, the cells 50 of array 200 are formed without using an extra FLASH/EE mask pattern, and implanted by a single asymmetric halo implant from only one select direction (e.g., rotation 2) corresponding to a drain region 55 side of the cell 50

The array 200 of FIG. 9 further illustrates that the isolation region STI 150 is formed between the source 54 and drain 55 regions of neighboring cells 50 to isolate the asymmetrically formed (asymmetrically implanted) source 54 and drain 55 regions. Accordingly, the source 54 and drain 55 regions obtain different doping concentrations and therefore generally require separate bitline contacts to each of the respective regions. For example, array 200 comprises a first bitline contact 210 from the source region 54 to the M1 metal level (e.g., Met1 110 of FIG. 7), and a second bitline contact 220 from the drain region 55 to the M2 metal level (e.g., Met2 120 of FIG. 7). In particular, since the source and drain regions are formed asymmetrically in isolated well or moat regions 140, separate bitline contacts 210 and 220 are used to accommodate different voltage bias conditions for the respective terminals during various memory operations.

Thus, the resulting transistors (e.g., NMOS memory cell transistors 50) of the array 100 of FIG. 7 or 200 of FIG. 9 of the FLASH EEPROM memory region (e.g., 11 of FIG. 2A) are fabricated asymmetrically in accordance with the method 70 of the invention of FIG. 6, while the transistors of the logic region 14 (e.g., LVCMOS region 12, or HVCMOS region 13 of FIG. 2A) are conventionally fabricated symmetrically. Consequently, the single-sided or drain selective halo implant of the present invention avoids the additional defects associated with implanting a second time on the source side of the gate/channel, avoids the second implant rotation and the time this requires, and avoids the added mask and costs required of a mask produced asymmetry.

Accordingly, the systems and methods of the present invention provide a memory device, for example, wherein the NMOS transistors of an FLASH EEPROM memory device having memory (FLASH/EEPROM) and logic (e.g., LVCMOS and/or HVCMOS) regions, exhibit improved programming performance of embedded memory technology due to the application of a single halo implant selective to the drain side of the channel, and reduced defects associated with the avoidance of the halo implant from the source side of the channel in the FLASH/EEPROM region of the device.

Further, while the invention is generally described above with respect to NMOS transistor fabrication within the memory (array) region (e.g., 11 of FIG. 2A) of an array (e.g., 10 of FIG. 2A), NMOS and PMOS transistors may be fabricated concurrently in the LVCMOS and HVCMOS logic regions (e.g., 12 and 13 of FIG. 2A) of the array (e.g., 10 of FIG. 2A).

Although the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, the term “exemplary” is merely meant to mean an example, rather than the best. It is also to be appreciated that layers and/or elements depicted herein are illustrated with particular dimensions relative to one another (e.g., layer to layer dimensions and/or orientations) for purposes of simplicity and ease of understanding, and that actual dimensions of the elements may differ substantially from that illustrated herein. Additionally, the layers can be formed in any number of suitable ways, such as with spin-on techniques, sputtering techniques (e.g., magnetron or ion beam sputtering), (thermal) growth techniques and/or deposition techniques such as chemical vapor deposition (CVD), for example.

What is claimed is:

1. A method of asymmetrically forming memory cell transistors of an embedded memory device having a logic region and a memory region, the method comprising:
masking over the memory region;
implanting a first conductivity type dopant in NMOS regions of CMOS logic transistors in the logic region in first and second implant directions;
masking over the logic region;
halo implanting the first conductivity type dopant in NMOS regions of the memory cell transistors in the memory region in the second implant direction only to reduce the number of masks required to make asymmetric memory cells and shorten programming time;
masking over the memory region; and
implanting a second conductivity type dopant in PMOS regions of the CMOS logic transistors in the logic region in the first and second implant directions.

2. The method of claim 1, further comprising initially forming a gate structure over a semiconductor body of the first conductivity type and defining a channel therebelow in the semiconductor body of the MOS transistors in the logic regions of the device before masking over the memory region and halo implanting with the first conductivity type dopant.

3. The method of claim 2, further comprising:
forming offset spacers on the lateral edges of the gate structure;
masking over the memory region and halo implanting with the first conductivity type dopant, wherein the halo implantations are aligned in the semiconductor body at an angle underlying the channel with respect to the lateral edges of the offset spacers; and
forming sidewall spacers over the lateral edges of the offset spacers.

4. The method of claim 1, further comprising forming source and drain extension regions of a second conductivity type formed in the semiconductor body in the source and drain regions on opposing sides of the channel of the MOS transistors in the logic and memory regions of the device.

5. The method of claim 1, wherein the implanting in the first implant direction comprises implanting at an angle underlying the channel from the source region side of the channel, and the implanting in the second implant direction comprises implanting at an angle underlying the channel from the drain region side of the channel.

6. The method of claim 1, wherein the logic region of the embedded memory device comprises a high voltage CMOS region and a low voltage CMOS region, and wherein the high voltage CMOS region is masked and implanted using one of LDD and halo implantations, or both, separately from one of the low voltage CMOS region and the memory region.

7. The method of claim 2, wherein the first conductivity type dopant is a p-type dopant and the second conductivity type dopant is an n-type dopant, and wherein the.

8. The method of claim 1, wherein the memory cell transistors of the embedded memory device having a semiconductor body of the first conductivity type comprises NMOS transistors of a 1T EEPROM memory cell.

9. The method of claim 1, further comprising forming isolation structures between the source and drain regions of neighboring cell transistors to isolate at least one of the doping differences produced between the neighboring source and drain regions and different voltage bias levels applied to metal contacts subsequently formed on the source and drain regions.

10. A method of asymmetrically forming memory cell transistors of an embedded memory device having a logic region and a memory region, the method comprising:
forming a gate structure over a semiconductor body of a first conductivity type and defining a channel therebelow in the semiconductor body of the transistors in the logic and memory regions of the device;
masking over the memory region;
LDD and halo implanting a first conductivity type dopant in NMOS regions of CMOS logic transistors in the logic region in first and second implant directions;
masking over the logic region;
halo implanting the first conductivity type dopant in NMOS regions of the memory cell transistors in the memory region in the second implant direction only to reduce the number of masks required to make asymmetric memory cells and shorten programming time;
masking over the memory region; and
LDD and halo implanting a second conductivity type dopant in PMOS regions of the logic transistors in the logic region in the first and second implant directions.

11. The method of claim 10, further comprising forming isolation structures between the source and drain regions of neighboring cell transistors to isolate at least one of the doping differences produced between the neighboring source and drain regions and different voltage bias levels applied to metal contacts subsequently formed on the source and drain regions.

12. The method of claim 10, wherein the implanting in the first implant direction comprises implanting at an angle underlying the channel from the source region side of the channel, and the implanting in the second implant direction comprises implanting at an angle underlying the channel from the drain region side of the channel.

13. The method of claim 10, wherein the logic region of the embedded memory device comprises a high voltage CMOS region and a low voltage CMOS region.

14. The method of claim 13, wherein the high voltage CMOS region is masked and implanted separately from one of the low voltage CMOS region and the memory region.
